(19) United States
(12) Patent Application Publication
(10) Pub. No.: US 2012/0083415 A1
(43) Pub. Date: Apr. 5, 2012

(54) PROCESS OF SUPERCONDUCTING WIRE AND SUPERCONDUCTING WIRE

(75) Inventors: Kazuhide Tanaka, Hitachi (JP); Yasuo Kondo, Hitachinaka (JP)

(73) Assignee: Hitachi, Ltd.

(21) Appl. No.: 13/227,493

(22) Filed: Sep. 8, 2011

(30) Foreign Application Priority Data
Sep. 30, 2010 (JP) 2010-220241

(51) Int. Cl. H01L 39/24

(52) U.S. Cl. 505/431; 29/599

(57) ABSTRACT

A process of a superconducting wire is provided, which includes a step for twisting a first wire with a second wire that is different from the first wire and a step for filling a twisted wire of the first wire and the second wire in a metal tube, or enveloping the twisted wire in a metal sheet. According to the process, for example, an MgB₂ superconducting wire that has a long homogeneity and high Jc can be obtained constantly.

### CROSS REFERENCE TO RELATED APPLICATIONS

This application claims the foreign priority benefit under Title 35, United States Code, §119(a)-(d) of Japanese Patent Application No. 2010-220241, filed on Sep. 30, 2010, the contents of which are hereby incorporated by reference.

### BACKGROUND OF THE INVENTION

1. Field of the Invention

The present invention relates to a process of superconducting wire and a superconducting wire.

2. Description of Related Art

A superconducting wire to be used for, for example, a superconducting magnet is required to have a high critical current density (Jc) and to homogenize Jc when the superconducting wire is elongated into a long wire.

As a process of MgB₂ superconducting wire, a Powder-In-Tube (PIT process) that forms a wire by filling a powder in a metal tube is a mainstream. In the PIT process, since a homogeneous filling of the powder in the longitudinal direction of the metal tube is difficult, a density distribution is generated in a superconducting core portion. As a result, a necking (cross sectional inhomogeneity) that causes a disconnection of the superconducting wire when it is elongated into a long wire is generated. The necking is such a phenomenon to lose a balance between thicknesses of the metal tube and the superconducting core portion, and thereby both the thicknesses vary in the longitudinal direction. As a result, the superconducting wire may be disconnected at a portion where the superconducting core portion has a larger cross section (the portion where the metal tube has a smaller cross section), and Jc may decrease locally at a portion where the superconducting core portion has a smaller cross section.

Then, a process of MgB₂ wire through a vapor-phase diffusion of Mg into a B wire has been proposed in, for example, “Superconductivity in Dense MgB₂ Wires” (Phys. Rev. Lett. 86, 2423 (2001)).

### SUMMARY OF THE INVENTION

### Problems to be Solved

However, in the method for diffusing a vapor of Mg into the B wire, an absolute supply amount of Mg is small. Therefore, a production of MgB₂ is limited only to a surface portion of the B wire, and thereby a high Jc is not obtained.

It is, therefore, an object of the present invention to provide a superconducting wire which has a high Jc as well as homogeneity when the superconducting wire is elongated into a long wire, and a process of the superconducting wire.

A process of a superconducting wire of the present invention, which solves the foregoing problems, includes a step that twists a first wire with a second wire to produce a conductor and fills the conductor in a metal tube. In addition, another process of the superconducting wire of the present invention includes a step that twists a first wire with a second wire to produce a conductor and envelops the conductor in a metal sheet. It is preferable that diameters of the first and the second wires are not more than 1 mm. In addition, it is preferable that the first and the second wires are annealed before the wires are filled in the metal tube, or enveloped in the metal sheet. In addition, after the conductor is filled in the metal tube or enveloped in the metal sheet, a work of elongation, a change of shape, and a heat treatment may be provided as appropriate.

Ag, Cu, Al or alloy of these metals may be used for the metal tube and the metal sheet. A barrier layer made of, for example, Ni, Nb, Ta or Fe may be disposed on inner side of the metal tube and the metal sheet.

It is preferable that a wire containing at least B and a wire containing at least Mg are used for the first wire and the second wire. It is more preferable that at least one of Li, Al and Zn is further contained in the wire containing Mg.

According to the foregoing configuration, a superconducting wire that has a high Jc as well as homogeneity in an elongated superconducting wire and a process of the superconducting wire can be provided.

### BRIEF DESCRIPTION OF THE DRAWINGS

FIG. 1 is a perspective view showing one example of a cross section of a superconducting wire;

FIG. 2A to FIG. 2C are perspective views showing one example of a process providing a barrier material and a stabilizing material to a superconducting wire;

FIG. 3 is a perspective view showing one example of a cross section of a superconducting wire; and

FIG. 4 is a perspective view showing one example of a cross section of a multi-filament superconducting wire.

### DETAILED DESCRIPTION OF THE PREFERRED EMBODIMENT

A superconductor exhibits superconductivity in an environment under a critical temperature (Tc). Almost one century has passed since Kamerlingh Onnes of Dutch discovered a superconducting phenomenon in 1911, and since then, many superconductors have been discovered.

A superconductor is applied to equipment, specifically, for example, a current lead, a power transmission cable, a large magnet, a nuclear magnetic resonance apparatus, a medical magnetic resonance diagnostic system, a superconducting electric power storage system, a magnetic separator, a magnetic field applied single crystal pulling apparatus, a refrigerator cooling superconducting magnet apparatus, a superconducting energy storage, a superconducting electric generator and a nuclear fusion furnace magnet. Especially, a medical magnetic resonance imaging system (MRI) and a nuclear magnetic resonance apparatus (NMR), which is used for a structural analysis of, for example, protein, are commonly used.

As a superconducting wire to be used for the equipment, wires of NbTi and Nb₃Sn are well known. The NbTi wire is processed by forming a composite of NbTi ingot and Cu. A km-long NbTi wire is processed at present, and this wire is the easiest to form a wire among various kinds of superconductors. In addition, a km-long Nb₃Sn wire is also processable at present by using a Bronze process or an internal diffusion process. However, critical temperatures (Tc) of NbTi and Nb₃Sn are low, and 9K and 18K, respectively. Therefore, it is difficult to maintain a superconducting state without using expensive liquid helium (4.2K) for the coolant. Accordingly, the cooling cost becomes expensive.

As a superconductor having a high critical temperature (Tc), oxide superconductors are known. A Bi-2223 wire, which is a typical one, is generally processed by the Power-In-Tube (PIT process) that forms a wire by filling a powder in a metal tube, and a km-long wire is processable at present. However, in the PIT process, it is required to use a noble metal for the metal tube as well as to align crystal grains. Then, the processing cost of the wire is not less expensive.

The MgB₂ superconductor was discovered in 21 century, and both characteristics of Tc and Hc₂ are equal to or superior to those of conventional metal superconductors. Therefore, a research for practical use of the MgB₂ superconductor has been actively promoted in the world after the discovery.

Specifically, the following characteristics are known.

(1) The critical temperature (Tc) is higher than that of conventional metal superconductors, and is 39K (More than 20K higher than the conventional temperature).
(2) The upper critical magnetic field (Hc₂) is higher than that of conventional metal superconductors, and is equal to or more than 20 T.
(3) The critical current density (Jc) is high. A practical use level of around 3000 A/mm² has been obtained in low magnetic field.
(4) The magnetic anisotropy is small. Then, an equal current flows in any directions of a-axis, b-axis and c-axis of the crystal (It is unnecessary to align crystal orientation of grains).

Therefore, by applying the MgB₂ superconductor to, for example, a superconducting magnet, a quenching accident can be suppressed and a highly-stable system can be built. In addition, since Tc is high, it is unnecessary to use liquid helium for the coolant, and a conduction cooling of the refrigerator and a coolant of liquid hydrogen or liquid neon may be used. Less expensive copper, iron, or stainless steel may be used for the metal tube of the MgB₂ wire.

As a method for forming a MgB₂ wire, as with a Bi-2223 wire, the PIT process, which is suitable for industrialization, is used. As a method for filling a powder in a metal tube by the PIT process, there are two methods, that is, a tapping filling method of a powder and a stacking filling method of a compact. Nowadays, through improvements of the process and heat treatment, improvements of Hcₜ and Jc have been progressed, and in a short sample of several cm-long, characteristics comparable with those of NbTi wire have been obtained. However, as described above, there are problems of disconnection due to a generation of necking and a local lowering of Jc, and thereby, it is difficult to obtain a wire that is excellent in a long length homogeneity and has a high transport critical current density (Jc).

Then, inventors of the present invention have earnestly studied a process of a superconducting wire and developed the present invention. According to the present invention, there is provided a process of a superconducting wire which includes a step that twists a first wire with a second wire to produce a conductor and a step that fills the conductor in a metal tube or envelops the conductor in a metal sheet. That is, the first wire is twisted with the second wire, and the twisted wires are filled in the metal tube or the twisted wires are enveloped in the metal sheet. Using a wire instead of a powder, as described above, it becomes unlikely to cause a density distribution like the case of powder filling. As a result, a superconducting wire that is excellent in long length homogeneity and has a high Jc can be stably processed. It is preferable to use a wire that is annealed just before being filled in a metal tube, or enveloped in a metal sheet. As described above, in a process such as the PIT process or the vapor diffusion process, it is difficult to combine both the long length homogeneity and high Jc. This is caused by degradation of workability due to a density variation in a wire core portion. Using the twisted wires, the density variation can be reduced, and as a result, a high long length homogeneity and a high transport critical current density (Jc) can be both obtained.

A metal tube or metal sheet improves electrical stability and has effects to maintain workability as a wire. It is preferable to use Ag, Cu, Al, or alloy of these metals, each of which has a low resistivity, for the metal tube and the metal sheet.

However, when a MgB₂ superconducting wire is processed, if Cu is used for the metal tube or metal sheet, Cu forms intermetallic compounds with Mg and superconductivity thereof is degraded. Then, it is preferable to dispose a barrier material, which suppresses diffusion reaction of Cu with Mg, between Cu and Mg. As the barrier material, for example, Ni, Nb, Ta or Fe may be used.

The present invention is preferably applied to a process of a MgB₂ superconducting wire. In this case, a wire containing Mg is twisted with a wire containing B, and after the twisted wires are elongated, the wire containing Mg is reacted with the wire containing B to produce MgB₂. In order to promote diffusion reaction when MgB₂ is produced, it is preferable that a diameter of each of the wires is not more than 1 mm. By setting the conditions as described above, a km-long wire having a high Jc not less than 1000 A/mm², which is a practical use level in magnetic field, while maintaining a value of the Jc, can be processed stably.

A lowering of MgB₂ production due to insufficient supply of Mg and B inhibits concurrent improvement of the long length homogeneity and high Jc. However, by twisting the wire containing Mg with the wire containing B, the density variation becomes small in the whole wire length, and B and Mg become close to each other. Therefore, a shortage of supply of Mg and B can be suppressed.

In addition, a superconducting phase of MgB₂ produced by this method has a high quality. That is, due to a laminar growth of MgB₂, a high density superconducting phase of MgB₂, which has not been obtained by the conventional method (for example, PIT process), can be obtained. Especially, since Mg and B are closely and directly contacted to each other after the wire is elongated, the diffusion reaction in the heat treatment is promoted.

It is preferable that any one of Li, Al and Zn, or a plurality of these metals are further added to a wire containing Mg. If Mg—Li alloy containing Mg as a major component or Mg—Zn alloy is used, a tensile strength can be improved. When Li is added to Mg, a structure of Mg having an hcp (hexagonal close-packed) structure that is poor in workability can be changed into a bcc (body-centered cubic) structure that has a rich workability through phase diagram, and as a result, a cold workability is largely improved. In addition, by adding Li that is a light element, the alloy is reduced in weight. On the other hand, a mechanical property can be improved by adding Al and a corrosion resistance as well as a mechanical strength can be improved by adding Zn.

In addition, an element such as Li, Al or Zn is dispersed into a superconducting wire and contributes to the pinning effect, thereby resulting in increase in the critical current. If Li is added, when a superconducting phase grows into laminar crystals, Li forms a Mg—Li—B alloy phase together with excess Mg and B. When Li is added to Mg, it is preferable that an adding amount of Li is not more than 35 at. %. Even if the alloy phase is formed, a path of superconducting current is not inhibited if the adding amount of Li is not more than 35 at. %.

In addition, if, for example, 0.2 to 30 volume % of Ag, Al, Ti, W, silicon oxide, silicon carbide, silicon nitride, or a mixture of them is added to Mg and B, Jc is improved. Especially, if a grain size is fined down to a nanometer scale, the improvement of Jc becomes more effective. In addition, by conducting a heat treatment in nitrogen gas, argon gas, hydrogen gas, oxygen gas or a mixture of them, or under a pressure more than the atmospheric pressure at a temperature between 200 and 1200° C., as needed, a bonding property between the grains is improved, thereby resulting in improvement of Jc.

A narrowing work of the wire is repeatedly conducted using a drawing bench, a hydrostatic extrusion, a swager, a cassette roller die, or a grooved roller at a cross section reduction rate of about 1 to 20% per/pass. A wire is formed into a multi-filament wire as needed. A method for forming the multi-filament wire is such that a plurality of elongated wires having a circular cross section or a hexagonal cross section are set in a pipe and elongated until a diameter of the wire is narrowed to a predetermined value at a cross section reduction rate of about 1 to 20% per/pass, using the foregoing tools. This is a common work process.

The process here has effects to form the wire into a desired shape as well as to highly densify the material filled inside a metal sheath material. In order to further densify the material, the material is rolled by a cold or hot rolling mill into a rectangular cross section or a tape and heat-treated at an appropriate temperature and atmosphere, as needed. Accordingly, a wire having a high critical current density can be obtained.

A superconducting wire can be applied to, for example, a superconducting magnet, an electric power transmission cable, a current lead, a MRI system, a NMR apparatus, a SEMS apparatus, a superconducting electric generator, a superconducting motor, a superconductive electromagnet ship, a superconducting transformer and a superconducting current-limiting device. A conductor that is a superconducting wire formed into a desired shape is incorporated into a coil, a current lead and a cable after the conductor is worked to change the shape suitable for the coil, the current lead and the cable. The processed wire may be used by combining two or more than two wires and winding it into a coil, or by forming the wire into the lead wire or the cable line, depending on the purpose.

Since a wire according to the present invention has a twisted structure, a mechanical strength of the wire such as a yield stress, a tensile stress and a Young's modulus is high. Therefore, for example, a magnet which can bear the electromagnetic force when a high intensity magnetic field is generated can be built. In addition, for example, a permanent current magnet may be realized by sufficiently reducing a resistance between both ends. In addition, if a temperature of the wire that can be used as a superconductor is higher than the temperature of liquid hydrogen or the temperature of liquid neon, the effects of the wire become more effective.

By applying the processed MgB₂ superconducting wire to equipment, the equipment can be operated by a cooling of liquid hydrogen, liquid neon, or a conduction cooling of a refrigerator, as well as the cooling of liquid helium. Accordingly, superconducting equipment that is compact as well as energy-saving can be realized.

In addition, when a superconductor which is processed according to the present invention is used, for example, in liquid helium, a practical conductor such as a superconducting magnet that generates a higher magnetic field can be realized by combining the superconductor with a metal superconductor, or oxide superconductor. In addition, when the superconductor processed according to the present invention is used in liquid hydrogen or liquid neon, the superconductor is combined with oxide superconductor. Two kinds or more than two kinds of magnets may be arranged, as needed. As a metal superconductor to be combined, for example, NbTi-based alloy, Nb Sn-based compound, Nb₃Al-based compound, V₃Ga-based compound, or a Chevrel-based compound is used. As an oxide superconductor, for example, a superconductor of Y-based, Bi-based, Ti-based, Hg-based, or (Ag, Pb)-based is used.

Hereinafter, a process of a superconducting wire which includes a step that twists a first wire with a second wire in order to produce a conductor and a step that fills the conductor in a metal tube or envelops the conductor in a metal sheet, will be specifically explained using examples. It is noted that the examples do not limit the present invention, and according to the spirits of the present invention, a design can be modified as appropriate in order to achieve the effects of the present invention.

### Example 1

As a starting material, a magnesium bar (hereinafter, referred to as Mg bar) 1 having a diameter of 0.2 mm (Mg: 98% purity) and a boron bar (hereinafter, referred to as B bar) 2 having a diameter of 0.2 mm (B: 98% purity) were used. The B bar 2 was prepared by conducting a reduction treatment of a B₂O₃ bar. The Mg bar 1 was arranged around the B bar 2, and twisted at 30 mm pitch to form a conductor 3 (see FIG. 1).

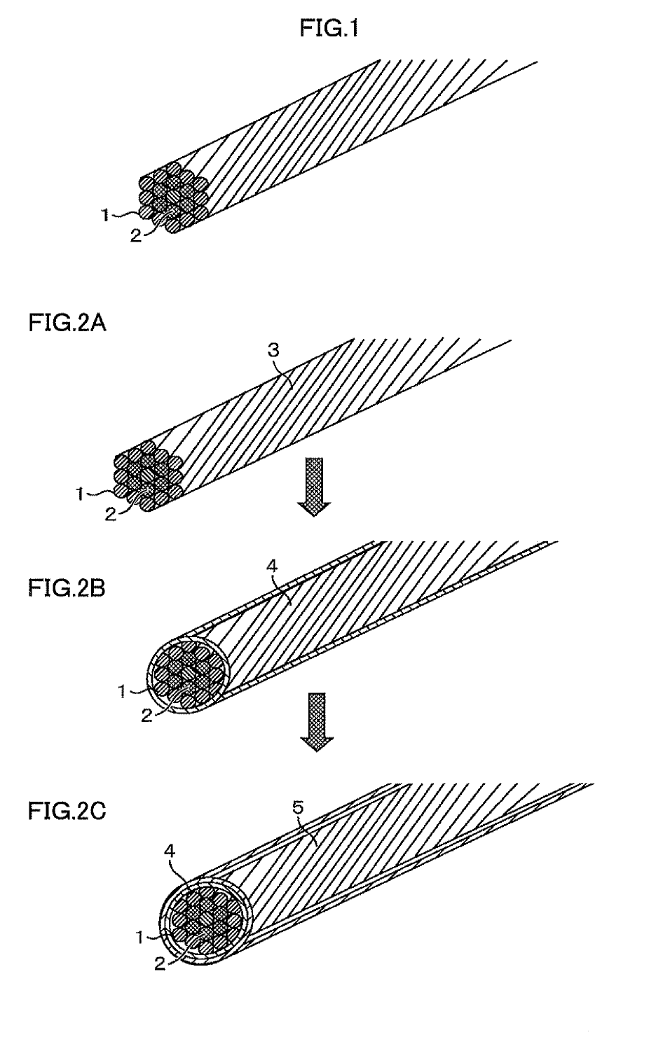

The conductor 3 having a length of 200 m shown in FIG. 2A was prepared, and first, the conductor 3 was spirally enveloped in an Nb sheet 4 having a thickness of 0.1 mm from an outer surface of the conductor 3 so that the Mg bar and the B bar therein were not exposed (see FIG. 2B). This Nb sheet has a role of a barrier material. In addition, the conductor 3 was further spirally enveloped in a Cu sheet having a thickness of 0.2 mm from an outer side of the Nb sheet 4 so that the Nb sheet 4 therein was not disposed (FIG. 2C). The Cu sheet 5 has a role of an electrical stabilizer. The conductor was elongated, and heat treated after the conductor was elongated in a desired shape (a reduction ratio of cross section is 8 to 15%) to prepare a superconducting wire (Cu-clad MgB₂ single core wire).

Using an elongated wire having an outer diameter of 1.0 mm as a sample, Jc was measured at 4.2K in 5 T. A length of the sample was 60 mm, and ten samples were picked up from the wire having the outer diameter of 1.0 mm at 5 m intervals. Then, Jc of about 800 A/mm² was constantly obtained for all of the ten samples.

Next, a working process limitation of the wire was confirmed through observation of an elongated wire having an outer diameter of less than 1.0 mm. If the working process limitation is defined by a die diameter that causes a disconnection of the wire equal to or more than three times in the elongation process, it was found that the outer diameter of the wire can be narrowed down to 0.85 mm in the elongation process.

### Example 2

In the present example, as a starting material, an Mg alloy bar was used instead of the Mg bar 1 of EXAMPLE 1. As a Mg alloy bar, (a) a Mg—Li alloy bar in which Li concentration is 15 at. % and (b) a Mg—Al—Zn alloy bar in which Al concentration is 3 at. % and Zn concentration is 1 at. %, were used. Other features and methods were identical to those of EXAMPLE 1 for processing a superconducting wire (Cu-clad MgB₂ single core wire).

As with EXAMPLE 1, Jc was measured at 4.2K in 5 T using an elongated wire having an outer diameter of 1.0 mm as a sample. A length of the sample was 60 mm, and ten samples were picked up from the wire having an outer diameter of 1.0 mm at 5 m intervals. Then, Jc of about 800 A/mm² was constantly obtained for all of the ten samples.

In addition, as with EXAMPLE 1, the working process limitation of a wire processed in EXAMPLE 2 was examined. As a result, it was found that if the Mg alloy bar was used, the outer diameter of the wire can be narrowed down to 0.37 mm in the elongation process. This narrowing result was the same in both (a) and (b) cases. From the fact described above, it is clear that Li addition to Mg, as well as Al and Zn addition to Mg contributes to improve workability of the wire without causing a lowering of Jc.

In addition, with respect to the Mg—Li alloy bar, a superconducting wire in which a Li concentration was increased was prepared. Then, it was found that if the Li concentration was not more than 35 at. %, an elongation workability and a lowering of Jc were not caused. Therefore, it was confirmed that if the Li concentration is not more than 35 at. %, a path of superconducting current is not inhibited even if a Mg—Li—B alloy phase is produced.

### Example 3

In this example, diameters of the Mg bar 1 and the B bar 2, which are starting materials, were changed. As a starting material, a Mg—Li alloy bar in which Li concentration is 15 at. % and a B bar were used. Diameters of the used starting materials are shown in TABLE 1. As with EXAMPLE 1, a Cu-clad MgB₂ single core wire (EXAMPLE 3-1 to EXAMPLE 3-7) was prepared. Meanwhile, a final target diameter of the wire was set to 1.0 mm in outer diameter of the wire.

TABLE 1

| | EXAMPLE | EXAMPLE | EXAMPLE | EXAMPLE | EXAMPLE | EXAMPLE | EXAMPLE |
|---|---|---|---|---|---|---|---|
| | 3-1 | 3-2 | 3-3 | 3-4 | 3-5 | 3-6 | 3-7 |
| Diameter of | 0.08 | 0.1 | 0.2 | 0.4 | 0.8 | 1.0 | 1.5 |
| Mg—Li bar (mm) | | | | | | | |
| Diameter of | 0.08 | 0.1 | 0.2 | 0.4 | 0.8 | 1.0 | 1.5 |
| B bar (mm) | | | | | | | |
| Critical current | 840 | 830 | 830 | 825 | 830 | 630 | 580 |
| density (A/mm²) | | | | | | | |

A critical current density (Jc) of each superconducting wire in TABLE 1 was measured at 4.2K in 5 T. As a result, it was found that if starting diameters of the Mg—Li alloy bar and the B bar were over 1 mm, Jc was decreased. By observing fine structures using an optical microscope, it was found that the decrease in Jc was caused by insufficient diffusion reaction in the heat treatment if the diameters were large. Therefore, when the starting diameter is large, it is required to change a final target diameter and heat treatment conditions.

### Example 4

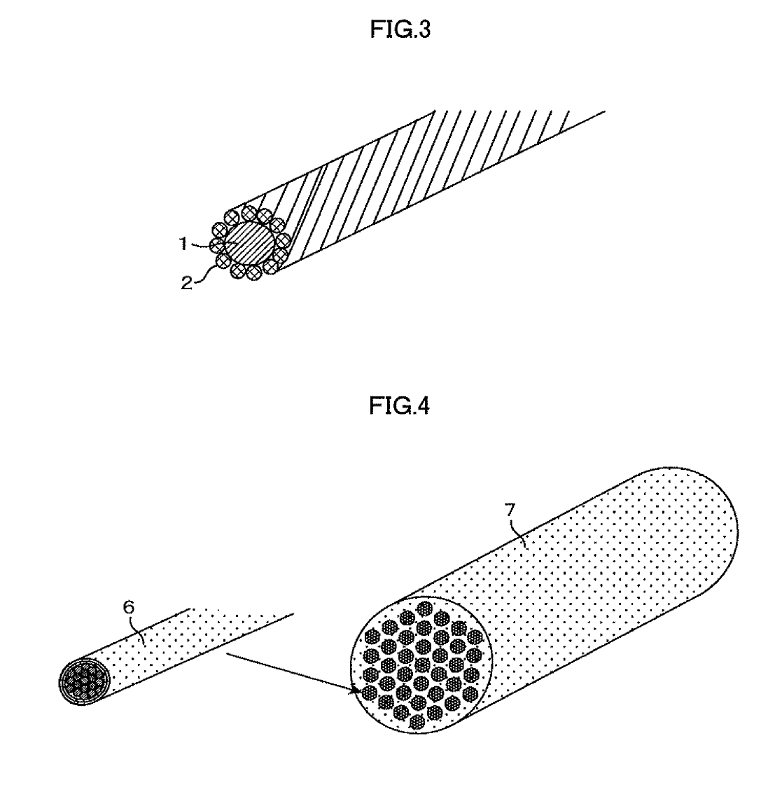

A case shown in FIG. 3 was examined, where a core was a large diameter metal bar, and other small diameter metal bars were spirally wound on the large diameter metal bar. A diameter of the Mg bar 1 was enlarged, and narrow B bars 2 were wound on the Mg bar 1 to form a superconducting wire. Then, it was found that if the diameter of the Mg bar 1 located at the center is decreased to not more than 1 mm, a wire having a high Jc can be obtained.

### Example 5

In the present example, starting materials were subjected to annealing. The starting materials that were used are identical to those of EXAMPLE 2. Before the Mg—Li alloy bar was twisted with the B bar, each starting material was annealed at a temperature of about 40 to 65% of a melting temperature of the each starting material. A superconducting wire was processed by a method similar to that of EXAMPLE 2.

As a result, when the starting materials were subjected to the annealing, the working process limitation of the outer diameter was improved up to 0.12 mm. It is noted that in the wire of EXAMPLE 2 that has no annealing process, the working process limitation of the outer diameter was 0.37 mm. As described above, the annealing of the Mg alloy bar and the B bar before the Mg alloy bar is twisted with the B bar is effective to improve the workability.

### Example 6

EXAMPLE 6 is a sample of a wire (multi-filament wire) 7 that has a multi-filament structure. The wire of EXAMPLE 5 was formed into the multi-filament structure. In the multi-filament structure, since a ratio of Cu (stabilizer) within a cross section of the wire increases, the elongation workability was further improved. The working process limitation of the multi-filament wire was 0.10 mm in outer diameter.

### Comparison Example 1

In the comparison example, a superconducting wire was formed using powder of Mg and B. As a starting material, Mg powders (Mg: 98% purity) having an average particle diameter of 45 μm and B powder (B: 90% purity) having an average particle diameter of not more than 5 μm, were used. The Mg powder and the B powder were weighted so that an atomic molar ratio of Mg to B is 1:2, and mixed to each other using a centrifugal ball mill in Argon atmosphere for two hours in order to obtain a filling powder.

An iron tube having an outer diameter of 14.5 mm and an inner diameter of 13 mm was set in a copper tube having an outer diameter of 20 mm and an inner diameter of 15 mm, and both tubes were unified by diffusion joining through a heat treatment. In this case, a brass foil was arranged between the iron tube and the copper tube as a joining aid. The filling powder was filled in the metal tube and repeatedly elongated at a cross section reduction rate of 8 to 15%.

The wire was able to elongate up to an outer diameter of 1.32 mm without disconnection. However, a disconnection began to occur at the outer diameter of 1.2 mm, and the disconnection was repeatedly occurred at the outer diameter of 1.0 mm at intervals of about 2 to 5 m. As with EXAMPLE 1, the working process limitation was estimated, and it was found that the working process limitation was 1.1 mm in outer diameter.

The wire was observed with an optical microscope, and it was found that a density inhomogeneity was generated in the filled powder. In addition, a cross section at the disconnection was observed, and it was confirmed that a powder area was larger (a metal sheath area was smaller locally) in comparison with a metal sheath area in the cross section at the disconnection.

Next, Jc was measured at 4.2K in 5 T, using an elongated wire having an outer diameter of 1.0 mm. Ten samples were picked up from the wire having the outer diameter of 1.0 mm at intervals of 5 m. A length of the sample was 60 mm. From the measurement, it was found that Jc varies from 250 A/mm² to 600 A/mm², and confirmed that the origin of the variation was the density inhomogeneity.

By comparing EXAMPLE 1 with COMPARISON EXAMPLE 1, it was demonstrated that EXAMPLE 1 is superior to COMPARISON EXAMPLE 1 for obtaining an MgB₂ superconducting wire that has a long homogeneity and high Jc.

What is claimed is:

1. A process of a superconducting wire, comprising:
twisting a first wire with a second wire that is different from the first wire; and
filling a twisted wire of the first wire and the second wire in a metal tube, or enveloping the twisted wire in a metal sheet.

2. The process of a superconducting wire according to claim 1, further comprising:
setting outer diameters of the first wire and the second wire not more than 1 mm.

3. The process of a superconducting wire according to claim 1, further comprising:
annealing at least one of the first wire and the second wire before the first wire and the second wire are filled in the metal tube, or enveloped in the metal sheet.

4. The process of a superconducting wire according to claim 1, further comprising:
setting a wire diameter of the first wire different from the wire diameter of the second wire.

5. The process of a superconducting wire according to claim 1, further comprising:
making a composition of the first wire different from the composition of the second wire.

6. The process of a superconducting wire according to claim 1, further comprising:
containing magnesium in the first wire and containing boron in the second wire.

7. The process of a superconducting wire according to claim 6, further comprising:
containing at least one of Li, Al and Zn in the first wire.

8. The process of a superconducting wire according to claim 7, further comprising:
setting a sum of the Li, Al and Zn not more than 35 at. %.
